(19) United States
(12) Patent Application Publication
(10) Pub. No.: US 2025/0300052 A1
(43) Pub. Date: Sep. 25, 2025

(54) SEMICONDUCTOR PACKAGE AND FABRICATING METHOD THEREOF

(71) Applicant: AaltoSemi Inc., Jiangsu (CN)

(72) Inventors: Yin-Ju CHEN, Jiangsu (CN); Min-Yao CHEN, Jiangsu (CN); Sung-Kun LIN, Jiangsu (CN); Jiun-Hua CHIUE, Jiangsu (CN); Andrew C. CHANG, Jiangsu (CN); Pei-Ching LI, Jiangsu (CN); Zhen-Hu CHANG, Jiangsu (CN)

(21) Appl. No.: 19/085,435

(22) Filed: Mar. 20, 2025

(30) Foreign Application Priority Data
Mar. 21, 2024 (CN) 202410329860.3

(51) Int. Cl. H01L 23/498; H01L 21/48; H05K 1/18

(52) U.S. Cl. CPC H01L 23/49822; H01L 21/4857; H01L 21/486; H01L 23/49838; H05K 1/181

(57) ABSTRACT

A semiconductor package is provided and includes a package substrate and an electronic component. The electronic component is embedded in the package substrate to reduce the height of the semiconductor package so that the semiconductor package matches the needs of thinning. A method of fabricating the semiconductor package is also provided.

### BACKGROUND

### 1. Technical Field

The present disclosure relates to a semiconductor packaging technology, and more particularly, to a semiconductor package having an embedded electronic component and a fabricating method thereof.

### 2. Description of Related Art

Current technologies in the field of chip packaging include types such as Chip Scale Package (CSP), Direct Chip Attached (DCA) and Multi-Chip Module (MCM). Typically, semiconductor chips are placed on a package substrate.

FIG. 1 shows a schematic cross-sectional view of a conventional semiconductor package 1. As shown in FIG. 1, a wiring structure 11 and circuit structures 13 with different circuit specifications are configured in a dielectric body 12 on a package substrate 10. A plurality of semiconductor components 19, such as processor dies and memory dies, are then placed on the wiring structure 11 and the circuit structures 13, so that the semiconductor components 19 are electrically connected to wiring layers 110 of the wiring structure 11 and circuit layers 130 of the circuit structures 13 via solder balls 17.

However, in the conventional semiconductor package 1, the semiconductor components 19 are disposed on the wiring structure 11 and the circuit structures 13, resulting in a height of the semiconductor package 1 that is difficult to reduce, thereby failing to meet the requirements of thinning.

Moreover, the semiconductor components 19 need the solder balls 17 so as to be electrically connected to the wiring layers 110 and the circuit layers 130, leading to signal transmission loss issues between the semiconductor components 19 and the wiring layers 110 and the circuit layers 130.

Furthermore, due to the different circuit specifications (such as line width or line spacing) of the wiring layers 110 and the circuit layers 130, it is difficult to fabricate the wiring layers 110 and the circuit layers 130 within the same dielectric body 12, resulting in extremely high manufacturing costs.

Therefore, how to overcome the above-mentioned issues in the conventional fabricating method has become a critical problem that needs to be solved.

### SUMMARY

In view of the various deficiencies of the prior art, the present disclosure provides a semiconductor package, which comprises: a package substrate, including: a core board having a first side, a second side opposite to the first side, and a plurality of conductive vias communicating the first side and the second side; a circuit structure formed on the first side and the second side of the core board and electrically connected to the plurality of conductive vias, wherein the circuit structure has at least one insulation layer, a first circuit layer formed on the insulation layer, and a plurality of conductive blind vias formed in the insulation layer and electrically connected to the plurality of conductive vias and the first circuit layer; a dielectric layer formed on each of the circuit structures; a first wiring layer embedded in the dielectric layer on the first side of the core board; a plurality of conductive pillars formed in the dielectric layer and electrically connected to the first wiring layer and the first circuit layer; and an electronic component disposed on the first side of the core board and electrically connected to the first circuit layer, wherein the electronic component is covered by the insulation layer, and the first circuit layer is electrically connected to the electronic component via at least one of the plurality of conductive blind vias.

The present disclosure also provides a method of fabricating a semiconductor package, the method comprises: providing a core board having a first side, a second side opposite to the first side, and a plurality of conductive vias communicating the first side and the second side; disposing an electronic component on the first side of the core board; forming a circuit structure on the first side and the second side of the core board to electrically connect the plurality of conductive vias and the electronic component, wherein the circuit structure has an insulation layer covering the electronic component, a first circuit layer formed on the insulation layer, and a plurality of conductive blind vias disposed in the insulation layer and electrically connected to the plurality of conductive vias, the electronic component and the first circuit layer; forming a dielectric layer on each of the circuit structures; embedding a first wiring layer in the dielectric layer on the first side of the core board; and forming a plurality of conductive pillars in the dielectric layer to electrically connect the first wiring layer and the first circuit layer.

In the aforementioned semiconductor package and method, the electronic component is an active component, a passive component, or a coreless wiring structure.

In the aforementioned semiconductor package and method, a surface of the first wiring layer is flush with a surface of the dielectric layer.

In the aforementioned semiconductor package and method, the first wiring layer has a plurality of annular alignment portions corresponding to the plurality of conductive pillars respectively.

In the aforementioned semiconductor package and method, the present disclosure further comprises forming a build-up structure on the dielectric layer on the second side of the core board, wherein the build-up structure is electrically connected to the first circuit layer.

As can be seen from the above, in the semiconductor package and the fabricating method thereof of the present disclosure, the electronic component is embedded in the package substrate, so that the height of the semiconductor package is reduced, and the semiconductor package can meet the requirements of thinning.

Furthermore, the electronic component is directly electrically connected to the conductive blind vias, so that signal transmission loss issues can be prevented from occurring between the electronic component and the first circuit layer.

Additionally, by embedding the electronic component with smaller circuit specifications, the circuit specifications (such as line width or line spacing) of the first circuit layer do not need to be partially changed. Therefore, only the same circuit specification process needs to be performed on the same insulation layer, thereby significantly reducing manufacturing costs.

### BRIEF DESCRIPTION OF THE DRAWINGS

FIG. 1 is a schematic cross-sectional view of a conventional semiconductor package.

FIG. 2A to FIG. 2G are schematic cross-sectional views illustrating a method of fabricating a semiconductor package according to a first embodiment of the present disclosure.

FIG. 3A to FIG. 3E are schematic cross-sectional views illustrating a method of fabricating a semiconductor package according to a second embodiment of the present disclosure.

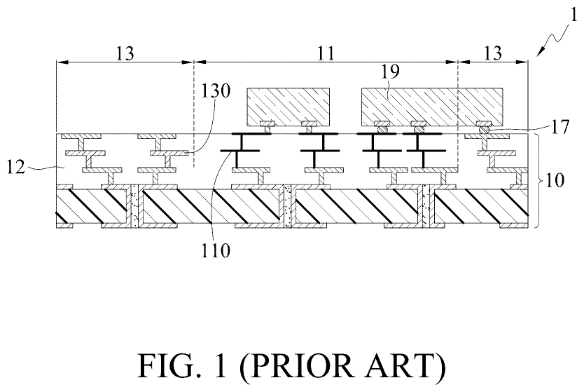

### DETAILED DESCRIPTION

The following describes the implementation of the present disclosure with examples. Those skilled in the art can easily understand other advantages and effects of the present disclosure from the content disclosed in this specification.

It should be understood that, the structures, ratios, sizes, and the like in the accompanying figures are used for illustrative purposes to facilitate the perusal and comprehension of the content disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical content disclosed in the present specification. Meanwhile, terms such as “on,” “first,” “second,” “a,” “one” and the like are merely used for clear explanation rather than limiting the practicable scope of the present disclosure, and thus, alterations or adjustments of the relative relationships thereof without essentially altering the technical content should still be considered in the practicable scope of the present disclosure.

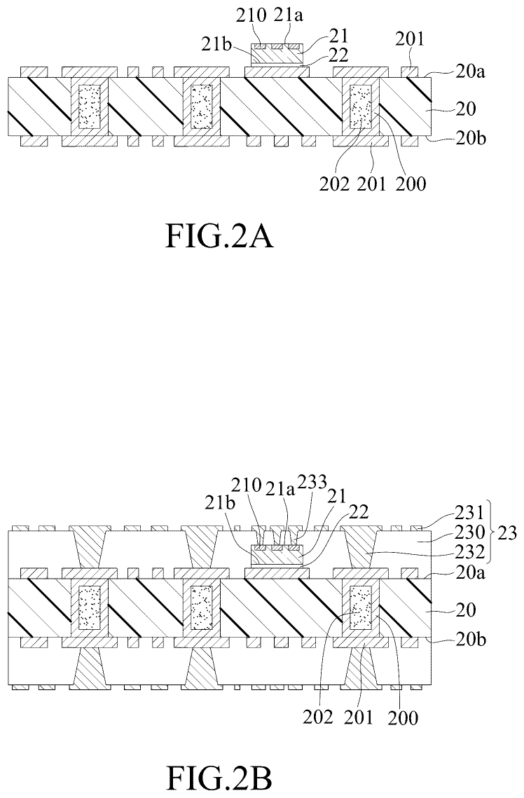

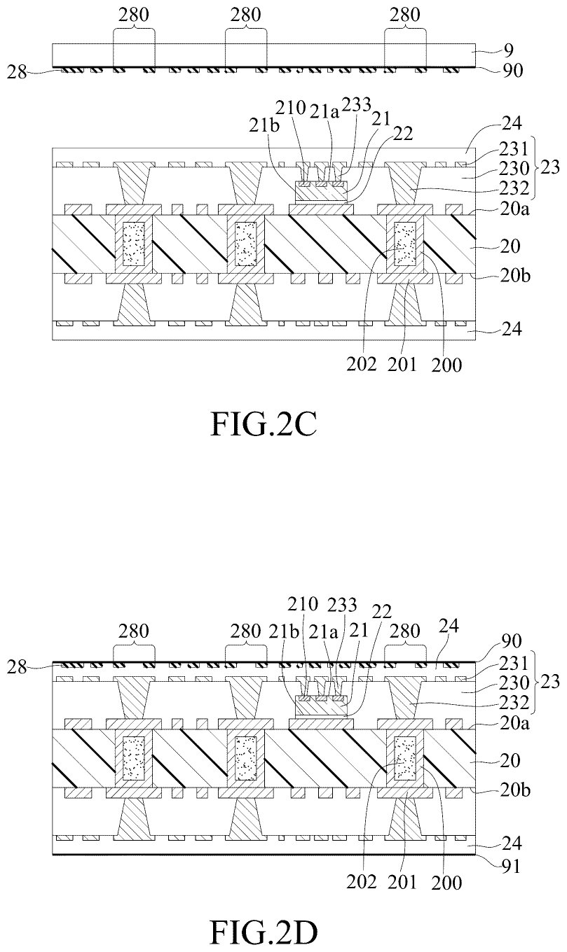

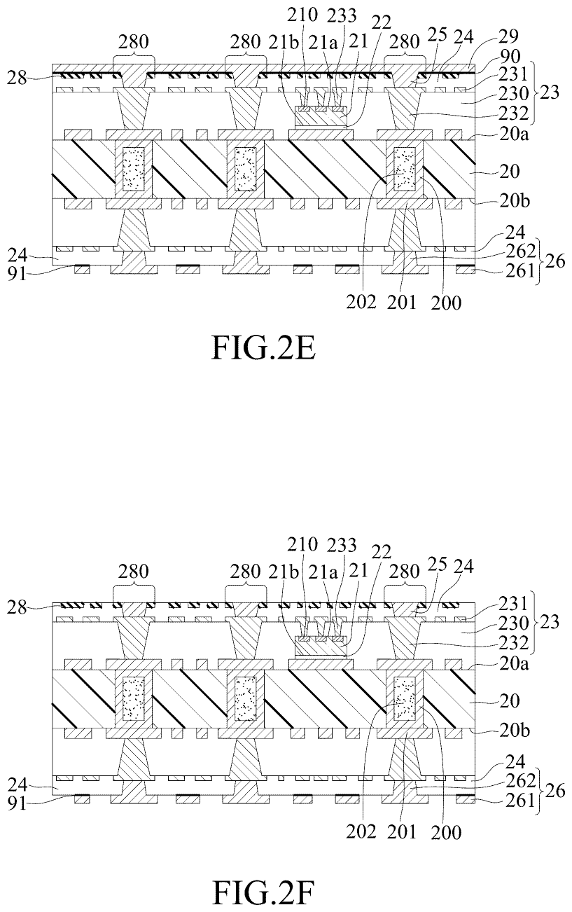

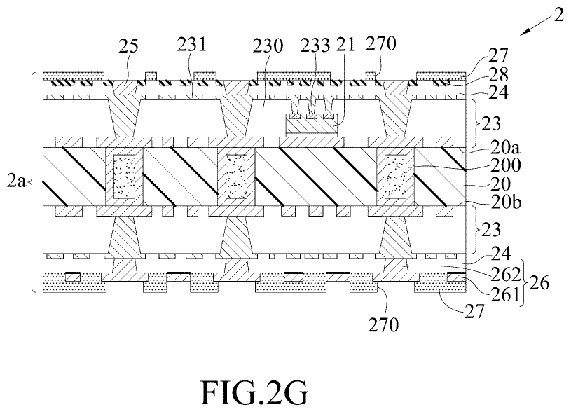

FIG. 2A to FIG. 2G are schematic cross-sectional views illustrating a method of fabricating a semiconductor package 2 according to a first embodiment of the present disclosure.

As shown in FIG. 2A, a core board 20 and an electronic component 21 disposed on the core board 20 are provided. The core board 20 has a first side 20a and a second side 20b opposite to the first side 20a, and internal circuit layers 201 are formed on both the first side 20a and the second side 20b of the core board 20. The electronic component 21 is bonded on the internal circuit layer 201 on the first side 20a. The core board 20 has a plurality of conductive vias 200 (e.g., conductive through vias) communicating the first side 20a and the second side 20b, and the conductive vias 200 are electrically connected to the internal circuit layers 201.

In an embodiment, the core board 20 can be made of an organic polymer substrate material containing bismaleimide triazine (BT) or prepreg (PP) with glass fiber, or other suitable materials. The conductive vias 200 are of hollow cylindrical structures that can be filled with a via-filling material 202, such as conductive adhesive or graphite (e.g., ink), without any particular limitation. It is also understood that in other embodiments, the conductive vias 200 can be solid metal pillars, eliminating the need for the via-filling material 202.

Additionally, the electronic component 21 can be an active component, a passive component, or a combination of the active component and the passive component. For instance, the active component can be a semiconductor chip, and the passive component can be a resistor, a capacitor, or an inductor. In an embodiment, the electronic component 21 is a semiconductor chip, such as a processor die or a memory die, and the electronic component 21 has an active surface 21a and an inactive surface 21b opposite to the active surface 21a. The active surface 21a is provided with a plurality of electrode pads 210. The inactive surface 21b of the electronic component 21 is bonded to the internal circuit layer 201 via an adhesive layer 22, with the active surface 21a facing outward.

As shown in FIG. 2B, circuit structures 23 are formed on both the first side 20a and the second side 20b of the core board 20. The circuit structures 23 are electrically connected to the electronic component 21 and the internal circuit layers 201.

In an embodiment, the circuit structures 23 can be formed using a build-up process on both the first side 20a and the second side 20b of the core board 20. The build-up process of the circuit structure 23 involves forming at least one insulation layer 230 covering the electronic component 21, a first circuit layer 231 on the insulation layer 230, and a plurality of conductive blind vias 232, 233 in the insulation layer 230 to electrically connect the internal circuit layer 201, the electrode pads 210 and the first circuit layer 231. For example, the insulation layer 230 is a dielectric layer and made of such as Ajinomoto build-up film (ABF), polybenzoxazole (PBO), polyimide (PI), prepreg (PP), or other dielectric materials. The first circuit layer 231 and the conductive blind vias 232, 233 can be integrally formed by electroplating metal (e.g., copper) or other methods.

It should be understood that the number of layers of the first circuit layer 231 can be designed as needed, and the depth of the conductive blind vias 232, 233 can be designed according to requirements, without being limited to the above description.

As shown in FIG. 2C, a carrier 9 is provided, and a dielectric layer 24 is formed on each of the circuit structures 23, so that the dielectric layers 24 cover the first circuit layers 231, such that the first circuit layers 231 on both the first side 20a and the second side 20b of the core board 20 are embedded in the dielectric layers 24.

In an embodiment, the carrier 9 includes a metal layer 90, and a first wiring layer 28 is formed on the metal layer 90. For example, the metal layer 90 and the first wiring layer 28 can both be made of metal such as copper, and the first wiring layer 28 has at least one annular alignment portion 280.

Furthermore, the dielectric layer 24 is made of such as Ajinomoto build-up film (ABF), polybenzoxazole (PBO), polyimide (PI), prepreg (PP), or other dielectric materials. For example, the material forming the insulation layer 230 and the dielectric layer 24 can be the same or different.

As shown in FIG. 2D, the carrier 9 is bonded to the dielectric layer 24, so that the first wiring layer 28 is embedded in the dielectric layer 24, and the metal layer 90 is bonded to the dielectric layer 24. Then, the carrier 9 is removed, and the metal layer 90 is remained on the dielectric layer 24.

In an embodiment, the first wiring layer 28 is formed by a lamination process on the dielectric layer 24 on the first side 20a of the core board 20. Thus, a metal layer 91, such as a copper layer, can be laminated on the dielectric layer 24 on the second side 20b of the core board 20, further pressing and bonding the dielectric layers 24 on both sides to the insulation layer 230 and the first circuit layer 231 via heat and pressure.

Furthermore, the position of the alignment portion 280 corresponds to the position of the deeper conductive blind via 232.

As shown in FIG. 2E, at least one conductive pillar 25 corresponding to the alignment portion 280 is formed in the dielectric layer 24 on the first side 20a of the core board 20, and a build-up structure 26 is formed on the dielectric layer 24 on the second side 20b of the core board 20.

In an embodiment, the process of forming the conductive pillars 25 involves first passing through the metal layer 90, and using laser ablation or other methods to form multiple openings in the dielectric layer 24, so that portions of the surface of the first circuit layer 231 are exposed from the openings. Then, copper is deposited on the walls of the openings using a chemical plating method to form a seed layer, followed by plating a copper layer 29 on the dielectric layer 24 and in the openings via the metal layer 90 and the seed layer, so that the copper layer 29 in the openings serves as the conductive pillars 25. Preferably, the alignment portions 280 are formed on the carrier 9 to facilitate laser alignment, making the openings in the dielectric layer 24 suitable for small-sized laser apertures, allowing the conductive pillars 25 to form fine-line/fine-pitch specifications.

Furthermore, the process of forming the build-up structure 26 also involves first passing through the metal layer 91. Multiple openings are formed in the dielectric layer 24 using laser ablation or other methods, so that portions of the surface of the first circuit layer 231 are exposed from the openings. Copper is then deposited on the walls of the openings using a chemical plating method to form a seed layer. Subsequently, a patterned circuit process is performed using the metal layer 91 and the seed layer to form a second circuit layer 261 on the dielectric layer 24, and a plurality of conductive blind vias 262 are formed in the openings to electrically connect the second circuit layer 261 and the first circuit layer 231, so that the second circuit layer 261 and the conductive blind vias 262 are served as the build-up structure 26. The exposed portions of the metal layer 91 not covered by the second circuit layer 261 are then removed to expose parts of the surface of the dielectric layer 24.

Moreover, the processes of forming the conductive pillars 25 and the build-up structure 26 can be performed concurrently. For example, a patterned resist layer (not shown) such as a dry film is formed on the dielectric layer 24 on the second side 20b of the core board 20, and the openings and parts of the surface of the seed layer of the metal layer 91 are exposed. Then, the copper layer 29, the conductive pillars 25 and the build-up structure 26 are formed. The patterned resist layer and the underlying metal layer 91 and seed layer are subsequently removed.

Additionally, since the insulation layer 230 needs to embed the electronic component 21, it is made using thicker prepreg material. In contrast, the dielectric layer 24 can be made using thinner prepreg material to facilitate the subsequent formation of the conductive pillars 25. Therefore, compared to the line width/line spacing (L/S) of the first circuit layer 231, the first wiring layer 28 has a smaller line width/line spacing (L/S), such as L/S≤10/10 micrometers (μm).

As shown in FIG. 2F, the metal layer 90, the seed layer and the copper layer 29 on the dielectric layer 24 on the first side 20a of the core board 20 are removed to expose the first wiring layer 28 and the conductive pillars 25.

In an embodiment, the surface of the first wiring layer 28 and the end surfaces of the conductive pillars 25 are flush with the surface of the dielectric layer 24 on the first side 20a of the core board 20.

As shown in FIG. 2G, a solder-resist layer 27 with multiple openings 270 is formed on each of the dielectric layers 24, so that portions of the surface of the first wiring layer 28, the end surfaces of the conductive pillars 25 and portions of the surface of the second circuit layer 261 are exposed from the openings 270, such that an asymmetric semiconductor package 2 is formed.

Therefore, in the fabricating method of an embodiment, the first wiring layer 28 and the conductive pillars 25 are embedded in the dielectric layer 24, which helps to increase the wiring density and facilitates subsequent processes. For example, solder material or other conductive bumps (not shown) can be formed on the first wiring layer 28 or the end surfaces of the conductive pillars 25, as in the bump on trace design, making the fabricating method of the present disclosure advantageous for thinning the semiconductor package 2.

Furthermore, the embedded first wiring layer 28 is suitable for copper electroplating to form electrical contact pads, providing better copper adhesion for the first wiring layer 28.

Additionally, a package substrate 2a carrying the electronic component 21 has greater rigidity due to the core board 20, and when combined with the core board 20, the insulation layers 230 and the dielectric layers 24 having similar coefficients of thermal expansion (CTE), the risk of warping in high-temperature environments is reduced.

Moreover, the electronic component 21 is embedded within the insulation layer 230 of the circuit structure 23 of the package substrate 2a, which not only increases the wiring density of the first circuit layer 231 but also avoids signal transmission loss between the electronic component 21 and the first circuit layer 231 due to the direct electrical connection with the conductive blind vias 233.

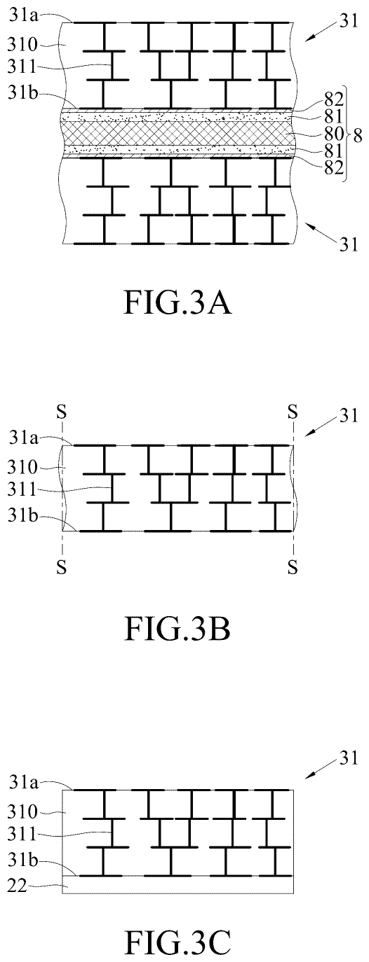

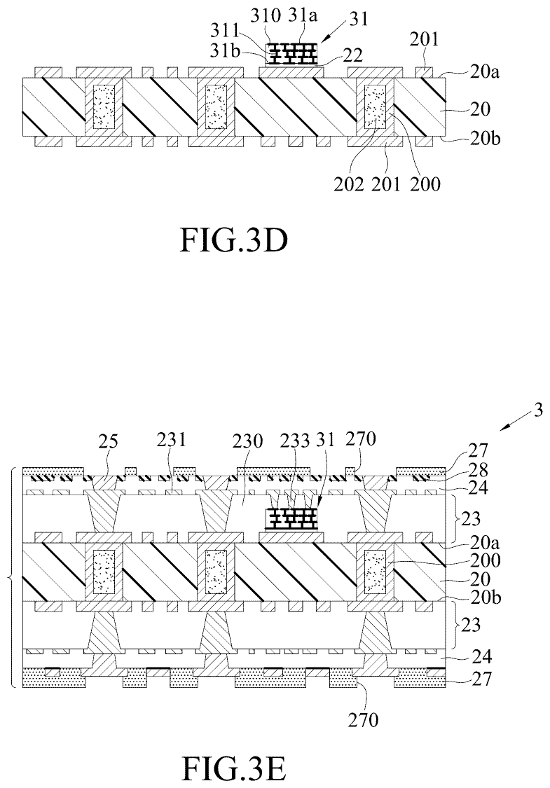

FIG. 3A to FIG. 3E are schematic cross-sectional views illustrating a method of fabricating a semiconductor package 3 according to a second embodiment of the present disclosure. The primary difference between the second embodiment and the first embodiment lies in the type of electronic component 31 used; the other processes are substantially the same and will not be repeated here.

As shown in FIG. 3A, a support member 8 is provided. An electronic component 31 is formed on each of the opposite sides of the support member 8. The electronic component 31 has a first surface 31a and a second surface 31b opposite to the first surface 31a, with the second surface 31b bonded to the support member 8.

In an embodiment, the support member 8 is a temporary carrier, which can be a substrate with metal layers on both opposite sides, such as a copper foil substrate. The surface of a support body 80 (e.g., a board body) of the support member 8 is provided with a release layer 81, and a metal layer 82, such as a copper layer, is formed on the release layer 81 to allow the electronic component 31 to be formed on the metal layer 82.

Furthermore, the electronic component 31 is of a coreless wiring structure, with at least one second wiring layer 311 formed in a dielectric body 310. For example, the dielectric body 310 is made of Ajinomoto build-up film (ABF), polybenzoxazole (PBO), polyimide (PI), prepreg (PP) with glass fiber, or other dielectric materials.

The second wiring layer 311 is formed using a build-up process by electroplating metal (such as copper) or other methods. For example, the second wiring layer 311 is made of copper and is fabricated to the specifications of a redistribution layer (RDL), making the second wiring layer 311 on the first surface 31a have extremely small line width/line spacing (L/S), such as L/S≤5/5 micrometers (μm). It is understood that the build-up process can be used to form the required number of layers of the second wiring layer 311 as needed.

As shown in FIG. 3B, the release layer 81 is used to separate the support body 80 of the support member 8 from the electronic component 31, and then the metal layer 82 on the second surface 31b of the electronic component 31 is removed by etching.

In an embodiment, the release layer 81 is removed by peeling or other methods to separate the support body 80 from the metal layer 82, and then the metal layer 82 on the second surface 31b of the electronic component 31 is removed by etching.

As shown in FIG. 3C, an adhesive layer 22 is applied to the second surface 31b of the electronic component 31, and then a singulation process is performed along the cutting path S shown in FIG. 3B to obtain multiple electronic components 31.

As shown in FIG. 3D, following the process shown in FIG. 2A, at least one electronic component 31 is placed on the internal circuit layer 201 of the core board 20 via the adhesive layer 22.

As shown in FIG. 3E, the processes shown in FIG. 2B to FIG. 2G are employed to form an asymmetric semiconductor package 3, where the shallow conductive blind vias 233 of the circuit structure 23 are electrically connected to the second wiring layer 311 of the electronic component 31.

Therefore, in an embodiment, the fabricating method involves placing the electronic component 31 (which is of a coreless wiring structure) in the insulation layer 230 of the package substrate 2a via bonding or other methods, and forming the shallow conductive blind vias 233 to electrically connect the first circuit layer 231 of the package substrate 2a. Compared to the prior art, the fabricating method of the present disclosure maintains the same specifications for the first circuit layer 231 without requiring different circuit specification processes for high-density wiring areas, thereby significantly reducing manufacturing costs.

The present disclosure also provides a semiconductor package 2, 3, which comprises: a package substrate 2a and at least one electronic component 21, 31. The package substrate 2a includes: a core board 20, at least one electronic component 21, 31, at least one circuit structure 23, at least one dielectric layer 24, a first wiring layer 28, and a plurality of conductive pillars 25.

The core board 20 has a first side 20a, a second side 20b opposite to the first side 20a, and a plurality of conductive vias 200 communicating the first side 20a and the second side 20b.

The electronic component 21, 31 is disposed on the first side 20a of the core board 20.

The circuit structure 23 is disposed on the first side 20a and the second side 20b of the core board 20 and electrically connected to the plurality of conductive vias 200 and the electronic component 21, 31, wherein the circuit structure 23 includes an insulation layer 230 covering the electronic component 21, 31, a first circuit layer 231 formed on the insulation layer 230, and a plurality of conductive blind vias 232 disposed in the insulation layer 230 and electrically connected to the plurality of conductive vias 200, the electronic component 21, 31 and the first circuit layer 231.

The dielectric layer 24 is respectively formed on each of the circuit structures 23.

The first wiring layer 28 is embedded in the dielectric layer 24 on the first side 20a of the core board 20.

The plurality of conductive pillars 25 are formed in the dielectric layer 24 and electrically connected to the first wiring layer 28 and the first circuit layer 231.

In one embodiment, the electronic component 21, 31 is an active component, a passive component, or a coreless wiring structure.

In one embodiment, a surface of the first wiring layer 28 is flush with a surface of the dielectric layer 24.

In one embodiment, the first wiring layer 28 has a plurality of annular alignment portions 280 corresponding to the plurality of conductive pillars 25 respectively.

In one embodiment, the semiconductor package 2, 3 further comprises a build-up structure 26 formed on the dielectric layer 24 on the second side 20b of the core board 20, wherein the build-up structure 26 is electrically connected to the first circuit layer 231.

In summary, in the semiconductor package 2, 3 and the fabricating method thereof of the present disclosure, the electronic component 21, 31 is embedded in the package substrate 2a, so that the height of the semiconductor package 2, 3 is reduced, and the semiconductor package 2, 3 can meet the requirements of thinning.

Furthermore, the electronic component 21, 31 is directly and electrically connected to conductive blind vias 233, so that signal transmission loss issues can be prevented from occurring between the electronic component 21, 31 and the first circuit layer 231.

Additionally, by embedding the electronic component 31 with smaller circuit specifications, the circuit specifications (such as line width or line spacing) of the first circuit layer 231 do not need to be partially changed. Therefore, only the same circuit specification process needs to be performed on the same insulation layer 230, thereby significantly reducing manufacturing costs.

The above embodiments are provided to illustrate the principles and effects of the present disclosure and are not intended to limit the scope of the present disclosure. Those skilled in the art can make modifications to the above embodiments without departing from the spirit and scope of the present disclosure. Therefore. the scope of protection for the present disclosure should be determined by the appended claims.

What is claimed is:

1. A semiconductor package, comprising:
a package substrate, including:
a core board having a first side, a second side opposite to the first side, and a plurality of conductive vias communicating the first side and the second side;
a circuit structure formed on the first side and the second side of the core board and electrically connected to the plurality of conductive vias, wherein the circuit structure has at least one insulation layer, a first circuit layer formed on the insulation layer, and a plurality of conductive blind vias formed in the insulation layer and electrically connected to the plurality of conductive vias and the first circuit layer;
a dielectric layer formed on each of the circuit structures;
a first wiring layer embedded in the dielectric layer on the first side of the core board;
a plurality of conductive pillars formed in the dielectric layer and electrically connected to the first wiring layer and the first circuit layer; and
an electronic component disposed on the first side of the core board and electrically connected to the first circuit layer, wherein the electronic component is covered by the insulation layer, and the first circuit layer is electrically connected to the electronic component via at least one of the plurality of conductive blind vias.

2. The semiconductor package of claim 1, wherein the electronic component is an active component, a passive component, or a coreless wiring structure.

3. The semiconductor package of claim 1, wherein a surface of the first wiring layer is flush with a surface of the dielectric layer.

4. The semiconductor package of claim 1, wherein the first wiring layer has a plurality of annular alignment portions corresponding to the plurality of conductive pillars respectively.

5. The semiconductor package of claim 1, further comprising a build-up structure formed on the dielectric layer on the second side of the core board and electrically connected to the first circuit layer.

6. A method of fabricating a semiconductor package, comprising:
providing a core board having a first side, a second side opposite to the first side, and a plurality of conductive vias communicating the first side and the second side;
disposing an electronic component on the first side of the core board;
forming a circuit structure on the first side and the second side of the core board to electrically connect the plurality of conductive vias and the electronic component, wherein the circuit structure has an insulation layer covering the electronic component, a first circuit layer formed on the insulation layer, and a plurality of conductive blind vias disposed in the insulation layer and electrically connected to the plurality of conductive vias, the electronic component and the first circuit layer;
forming a dielectric layer on each of the circuit structures;
embedding a first wiring layer in the dielectric layer on the first side of the core board; and
forming a plurality of conductive pillars in the dielectric layer to electrically connect the first wiring layer and the first circuit layer.

7. The method of claim 6, wherein the electronic component is an active component, a passive component, or a coreless wiring structure.

8. The method of claim 6, wherein a surface of the first wiring layer is flush with a surface of the dielectric layer.

9. The method of claim 6, wherein the first wiring layer has a plurality of annular alignment portions corresponding to the plurality of conductive pillars respectively.

10. The method of claim 6, further comprising forming a build-up structure on the dielectric layer on the second side of the core board, wherein the build-up structure is electrically connected to the first circuit layer.
